(19) United States
(12) Patent Application Publication
(10) Pub. No.: US 2006/0158249 A1
(43) Pub. Date: Jul. 20, 2006

(54) Linear amplifier and schmitt trigger using an analogue switch

(76) Inventors: Robert Anthony Currell, Truro (GB); Dennis Jaques, St Ives (GB)

Correspondence Address: James E Bradley;Bracewell & Giuliani, PO Box 61389, Houston, TX, 77208-1389, US

(21) Appl. No.: 10/559,753

(22) PCT Filed: Apr. 28, 2004
(86) PCT No.: PCT/GB04/01851

§ 371 Date: Dec. 7, 2005

(30) Foreign Application Priority Data
Jun. 7, 2003 (GB) 0313189.3

(51) Int. Cl. H03F 1/36

(52) U.S. Cl. 330/86

(57) ABSTRACT

A linear amplifier has an input terminal and an analogue switch. A switch input is connected to the input terminal and a switch output is connected to the switch input to provide negative feedback. The switch output may be connected to an output terminal. The switch may also be connected to a supply voltage. Preferably the switch input is connected to the input terminal via a first resistance, and the switch output is connected to the input terminal via a second resistance, so that a closed loop gain of the amplifier may be determined from the ratio of the second and first resistances.

The present invention concerns a linear amplifier and a Schmitt trigger which make use of an analogue switch.

Modern fluid extraction systems, for example hydrocarbon extraction wells, involve the installation of electronics downhole where the environmental temperature can typically be around 220° C. Therefore it is desirable to use electronic devices which can perform electronic functions at these temperatures. There are presently few integrated circuits which have been designed specifically to operate at such temperatures that are commercially available. However, wideband linear amplifiers and Schmitt triggers, both of which are important downhole components, are not yet commercially available which can operate satisfactorily at these temperatures.

It is an object of the present invention to provide a linear amplifier and a Schmitt trigger which are suitable for use at high temperatures. This object is achieved by constructing the devices using an analogue switch.

In accordance with a first aspect of the present invention there is provided a linear amplifier comprising an input terminal and an analogue switch, with a switch input connected to the input terminal and a switch output connected to the switch input to provide negative feedback.

The switch output may be connected to an output terminal.

The switch may also be connected to a supply voltage.

Preferably, the switch input is connected to the input terminal via a first resistance, and the switch output is connected to the input terminal via a second resistance, so that a closed loop gain of the amplifier may be determined from the ratio of the second and first resistances.

In a preferred embodiment, the analogue switch is configured to operate at temperatures of at least 200° C.

In accordance with a second aspect of the present invention there is provided a Schmitt trigger comprising an input terminal and an analogue switch, with a switch input connected to the input terminal and a switch output connected to the switch input to provide positive feedback.

The switch output may be connected to an output terminal.

The switch may also be connected to a supply voltage.

Preferably, the switch input is connected to the input terminal via a first resistance, and the switch output is connected to the switch input via a second resistance.

In a preferred embodiment, the analogue switch is configured to operate at temperatures of at least 200° C.

The invention will now be described by way of example with reference to the following figures, in which:-

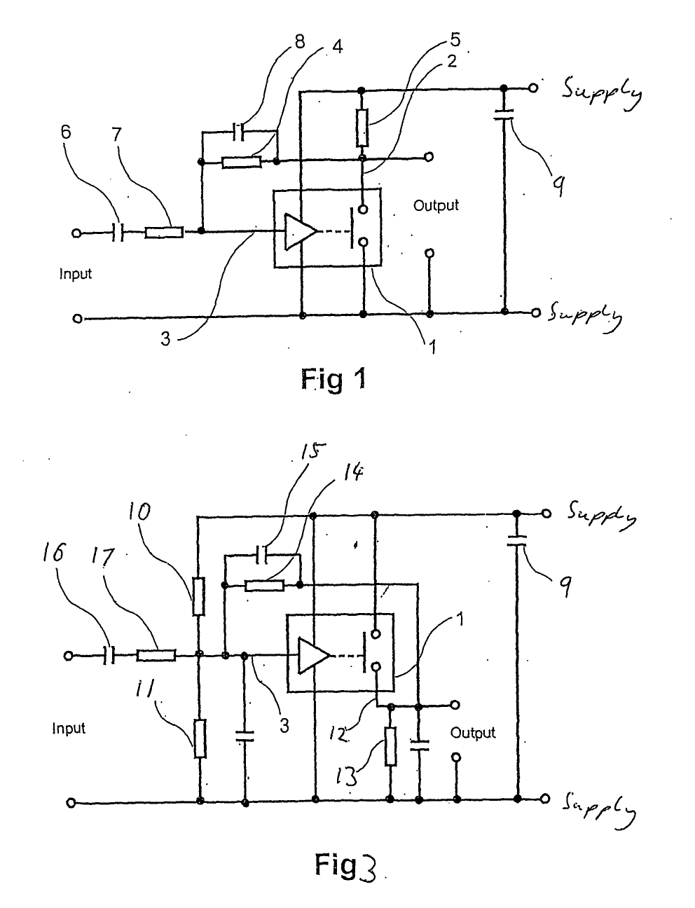

FIG. 1 shows a schematic circuit diagram of a linear amplifier in accordance with a first embodiment of the present invention;

FIG. 2 shows a schematic circuit diagram of a known analogue switch suitable for use with the present invention; and

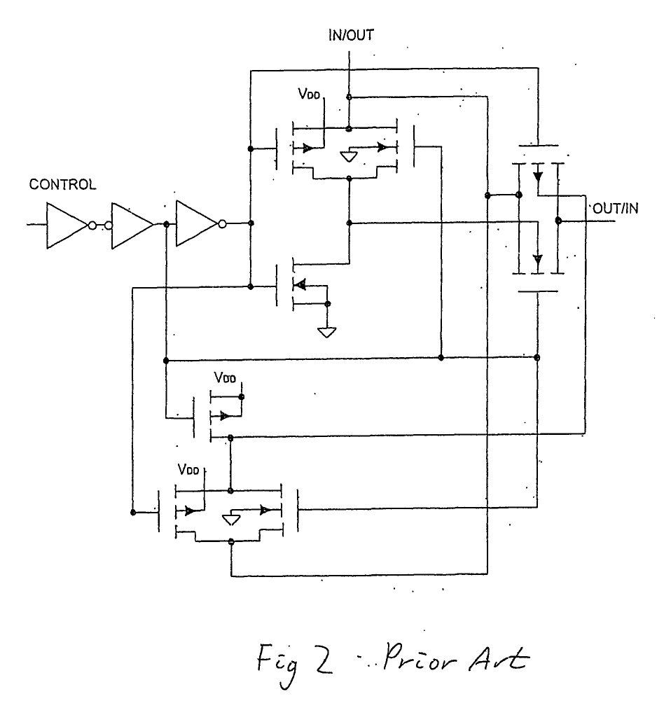

FIG. 3 shows a schematic circuit diagram of a Schmitt trigger in accordance with a second embodiment of the present invention.

A configuration of a linear amplifier according to a first embodiment of the present invention is shown in FIG. 1. The device comprises an analogue switch 1, which is preferably suitable for use at high temperatures, for example temperatures of at least about 200° C. An example of a suitable analogue switch is the quadruple analogue switch device HT 1204 DC manufactured by Honeywell, which is specifically designed for use at high temperatures and may operate satisfactorily at 225° C. FIG. 2 shows a schematic circuit diagram of one of the switches of the known Honeywell HT 1204 DC analogue switch device. The internal circuitry is shown as comprising three cascaded gates which act as amplifiers. These drive an arrangement of 8 field effect transistors (FETs). The high gain of the amplifiers results in a switching action of the FETs under normal use of the device.

The internal circuitry of such an analogue switch is shown simplified in FIG. 1 as an amplifier and a switch. The analogue switch is powered by connection to a supply voltage. An output 2 from the switch is connected to an input 3 of the switch via a resistance 4, so as to provide negative feedback from the switch output to the switch input. The switch output 2 is also connected to a voltage supply via a load resistance 5, which has a typical value of about 1 kΩ. The switch input 3 is connected to an input terminal via a capacitance 6 and a resistance 7. The capacitance 6 provides DC isolation for the circuit. The closed loop gain of the configuration is the ratio of the resistances 4 and 7. Typically, resistance 4 is about 100 kΩ and resistance 7 is about 1 kΩ, resulting in a gain of around 100. A capacitance 8, typically about 3 pF, is connected across resistance 4 to provide improved high frequency stability by compensating for the input capacitance of the device. A capacitance 9, typically about 100 nF, decouples the supply at high frequencies. The supply voltage will typically be greater than about 8 V, preferably around 10 V. With this arrangement, the negative feedback prevents the output from switching, leaving the configuration to operate as a linear amplifier. The bandwidth of this linear amplifier is at least 1 MHz.

FIG. 3 shows the layout of a Schmitt trigger according to the invention, where as far as possible similar components to the first embodiment have been given the same reference numerals. The circuit comprises an analogue switch 1, similar to that used in the first embodiment above, powered by connection to a supply voltage. The analogue switch has a switch input 3 connected to an input terminal via a capacitance 16, typically about 220 pF, and a resistance 17, typically about 1 kΩ. The capacitance 16 provides DC isolation for the circuit. The switch input 3 is biassed close to the switching threshold by resistances 10, typically about 12 kΩ, and 11, typically about 10 kΩ. An output 12 from the switch 1 is connected to a load resistance 13, typically about 510 Ω, and is also connected to the switch input 3 via a resistance 14. The resistance 14 provides positive feedback to the switch input 3. A capacitance 15, typically about 22 pF, is connected across resistance 14 to provide high frequency positive feedback hysteresis). The switch output 12 is also connected to an output terminal. A capacitance 9, typically about 100 nF, acts to decouple the supply at high frequencies.

As the input voltage level rises above a threshold level, the current through resistance 13 rises, as does the voltage across it. This increased voltage is fed back to the input 3 via the resistance 14 and capacitance 15, thus creating a regenerative action causing the output to switch high. Reducing the input voltage reverses the process but with hysteresis, thus providing some degree of noise immunity as with a conventional Schmitt trigger circuit. With this configuration the supply voltage can typically be around 5 V, and may operate with a bandwidth of better than about 7 MHz.

The above embodiments are by way of example only, and many possibilities and alternatives are possible within the scope of the claims.

1. A linear amplifier comprising an input terminal and an analogue switch, with a switch input connected to the input terminal and a switch output connected to the switch input to provide negative feedback.

2. A linear amplifier according to claim 1 wherein the switch output is connected to an output terminal.

3. A linear amplifier according to claim 1, wherein the switch is connected to a supply voltage.

4. A linear amplifier according to claim 1, wherein the switch input is connected to the input terminal via a first resistance.

5. A linear amplifier according to claim 4, wherein the switch output is connected to the input terminal via a second resistance.

6. A linear amplifier according to claim 5, wherein a closed loop gain of the amplifier is determined from the ratio of the second and first resistances.

7. A linear amplifier according to claim 1, in which the analogue switch is configured to operate at temperatures of at least 200° C.

8. (canceled)

9. A Schmitt trigger comprising an input terminal and an analogue switch, with a switch input connected to the input terminal and a switch output connected to the switch input to provide positive feedback.

10. A Schmitt trigger according to claim 9, wherein the switch output is connected to an output terminal.

11. A Schmitt trigger according to claim 9, wherein the switch is connected to a supply voltage.

12. A Schmitt trigger according to claim 9, wherein the switch input is connected to the input terminal via a first resistance.

13. A Schmitt trigger according to claim 12, wherein the switch output is connected to the switch input via a second resistance.

14. A Schmitt trigger according to claim 9, in which the analogue switch is configured to operate at temperatures of at least 200° C.

15. (canceled)
